(19) United States
(12) Patent Application Publication
(10) Pub. No.: US 2010/0084711 A1
(43) Pub. Date: Apr. 8, 2010

(54) ELECTROSTATIC DISCHARGE PROJECTION SEMICONDUCTOR DEVICE AND METHOD FOR MANUFACTURING THE SAME

(76) Inventors: Jong-Min Kim, Guro-gu (KR); Jong-Kyu Song, Gangsao-gu (KR); San-Hong Kim, Bucheon-si (KR)

Correspondence Address: SHERR & VAUGHN, PLLC, 620 HERNDON PARKWAY, SUITE 320, HERNDON, VA, 20170, US

(21) Appl. No.: 12/545,271

(22) Filed: Aug. 21, 2009

(30) Foreign Application Priority Data
Oct. 2, 2008 (KR) 10-2008-0097104

(51) Int. Cl. H01L 29/78; H01L 21/336

(52) U.S. Cl. 257/355; 438/306; 257/E29.266; 257/E21.437

(57) ABSTRACT

An electrical device, including a semiconductor device such an electrostatic discharge protection semiconductor device, and a method for manufacturing the same. An electrostatic discharge protection semiconductor device may include a substrate and a gate in and/or over the substrate. The gate may be multi-layered, and may include a gate oxide layer and a gate electrode. An electrostatic discharge protection semiconductor device may include a source region formed in and/or over a predetermined area of the substrate on a side of the gate, and a plurality of drain regions which may be sequentially multi-layered in and/or over the substrate on an opposing side of the gate in a vertical direction. At least one drain region may be overlapped with the gate in a horizontal direction.

The present application claims priority under 35 U.S.C. 119 to Korean Patent Application No. 10-2008-0097104, filed on Oct. 2, 2008, which is hereby incorporated by reference in its entirety.

### BACKGROUND

Embodiments relate to an electrical device. Some embodiments relate to a semiconductor device, such as an electrostatic discharge projection semiconductor device, and a method for manufacturing the same.

Recently semiconductor devices, such as high voltage semiconductor devices, have been developed and used in a wide variety of applications including liquid crystal display (LCD), integrated circuit (IC), and like technologies. The voltage used in high voltage semiconductor devices may be as high as approximately 30V. Therefore, high voltage semiconductors may be subject to physical damage resulting from high voltages and/or currents generated by, for example, an electrostatic discharge pulse.

An electrostatic discharge projection semiconductor device may be used to protect a high voltage semiconductor device from an electrostatic discharge pulse. An electrostatic discharge protection semiconductor device generally requires a relatively high triggering voltage and/or holding voltage with an increase in operation voltage of a semiconductor device. An electrostatic discharge protection semiconductor device including a diode may be used in an operation region that requires a relatively high triggering voltage and/or holding voltage, but may also require a substantially and relatively large region. To address size efficiency, a grounded gate MOSFET (metal oxide semiconductor field effect transistor) may be used as an electrostatic discharge protection semiconductor device. However, it may be difficult for a grounded gate MOSFET to gain relatively high holding voltage and/or current.

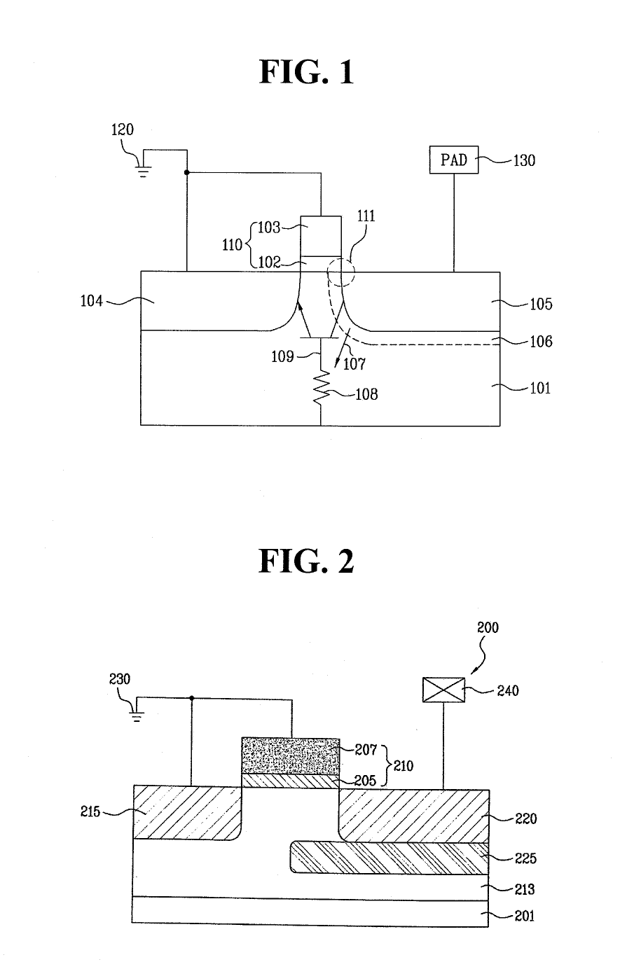

FIG. 1 is a sectional view illustrating a grounded gate MOSFET that may be used for electrostatic discharge protection. Referring to FIG. 1, the electrostatic discharge protection grounded gate MOSFET may include gate 110 formed in and/or over substrate 101. A grounded gate MOSFET may include source region 104 formed in and/or over a predetermined area of substrate 101 on a side of gate 110. A grounded gate MOSFET may also include a drain region 105 formed in and/or over a predetermined area of substrate 101 on an opposing side of gate 110. Gate 110 may be multi-layered, and may include gate oxide layer 102 and/or gate electrode 103. Gate electrode 103 and source region 104 may be connected to ground terminal 120. Drain region 105 may be connected to pad 130.

In operation, a relatively high voltage may be applied to drain region 105 and substrate 101 when static electricity is supplied to pad 130. The applied relatively high voltage may generate substrate current from impact ionization, and parasitic bipolar transistor 109 may be formed and/or operated. For example, an electric field may be concentrated over depletion region 106 and electrons in substrate 101 located adjacent to depletion region 106 may be supplied to drain region 105 to generate impact ionization. As a result, avalanch breakdown may occur and Hall current 107 generated by impact ionization may flow to bulk terminal 108 of substrate 101. As Hall current 107 flows to bulk terminal 108, an electric potential difference may be generated in bulk terminal 108 and parasitic bipolar transistor 109 may be operated. Therefore, an electrostatic discharge protection grounded gate MOSFET may be triggered.

After an electrostatic discharge protection grounded gate MOSFET is triggered, most of the current may be intensively supplied to a drain surface. A relatively high electric field may be formed in lower edge gate area 111 and/or adjacent to a relatively high density drain region. Therefore, heat may be generated therein. Further, an electron and a hole that may be impact-ionized in lower edge gate area 111 may deplete an interface between substrate 101 and gate oxide layer 102 such that leakage current may be generated. Thus, there is a need for an electrical device, including a semiconductor device such as an electrostatic discharge projection semiconductor device, that may protect an interface between a substrate and a gate oxide layer from damage, and that may reduce abnormal leakage current.

### SUMMARY

Embodiments relate to an electrostatic discharge protection semiconductor device and a method for manufacturing the same. According to embodiments, an electrostatic discharge protection semiconductor device may enable safe operation thereof by dispersing heat and/or electric currents intensively supplied to a junction between a drain region and a substrate and/or an interface between a substrate and a gate oxide layer.

Embodiments relate to an electrostatic discharge protection semiconductor device. According to embodiments, an electrostatic discharge protection semiconductor device may include a substrate and a gate. In embodiments, a gate may include a gate oxide layer and a gate electrode, and may be multi-layered in and/or over a substrate. In embodiments, a source region may be formed in and/or over a predetermined area of a substrate on a side of a gate. A plurality of drain regions may be formed in and/or over a substrate, and may be sequentially multi-layered in accordance with embodiments. In embodiments, one or more drain regions may be formed in and/or over an opposing side of a gate relative to a source region, in a vertical direction. In embodiments, at least one drain region may be overlapped with a gate in a horizontal direction.

According to embodiments, at least one drain region may be overlapped with a gate in a horizontal direction such that the overlapped area increases toward a lower area of the substrate. In embodiments, a plurality of drain regions may include a first drain region formed in and/or over a substrate on an opposing side of a gate relative to a source region. In embodiments, a second drain region may be formed substantially relatively deeper compared to a first drain region, and may be partially overlapped with a gate in a horizontal direction.

According to embodiments, an electrostatic discharge protection semiconductor may include a first conductivity type first well formed in and/or over a substrate. In embodiments, a source region, first drain region and second drain region may be formed in a first conductivity type well. In embodiments, a first drain region may be partially overlapped with a gate. In embodiments, an overlapped region between a first drain region and a gate may be substantially larger than an overlapped region between a second drain region and a gate.

According to embodiments, an electrostatic discharge protection semiconductor device may include a first conductivity type second well formed adjacent to a source region, and may be overlapped with a predetermined area of a gate adjacent to a source region. In embodiments, a density of impurity doped in a second drain region may be substantially higher than a density of impurity doped in a first drain region.

Embodiments relate to a method of manufacturing an electrostatic discharge protection semiconductor device. According to embodiments, a method may include forming a first conductivity type first well by selectively implanting a first conductivity type impurity ion in a substrate. The method may include forming at least one lower drain region by selectively implanting a second conductivity type impurity ion in a first well. In embodiments, at least one lower drain region may be multi-layered in and/or over a first conductivity first well, and may be spaced apart a predetermined distance from a surface of a first well. The method may include forming a gate in and/or over a substrate. In embodiments, a gate may be overlapped with a predetermined area of at least one lower drain region in a horizontal direction. The method may include forming an upper drain region in contact with an upper area of at least one lower drain region in and/or over a surface of a first well. In embodiments, forming an upper drain region may include implanting a second conductivity type impurity ion in a first well using a gate as an ion implantation mask.

According to embodiments, forming at least one lower drain region may increase the region downwardly from a top thereof in a horizontal direction. In embodiments, forming at least one lower drain region may include forming a first drain region by selectively implanting a second conductivity type impurity ion in a first well. In embodiments, forming at least one lower drain region may include forming a second drain region expanded to contact an upper area of a first drain in and/or over a surface of a first well by selectively implanting a second conductivity type impurity ion in a first well.

According to embodiments, forming a gate may include forming a gate in and/or over a substrate. In embodiments, forming a gate may include forming a gate overlapped with predetermined areas of a first and/or second drain regions, respectively, or overlapped with a predetermined area of a first drain region and not with a second drain region. In embodiments, the method may include forming a second well having a higher density than a first well in and/or over a first well adjacent to a source region prior to a gate, such that a second well may be spaced apart from first and second drain regions.

Embodiments relate to channels whose length may be reduced according to a depth, such that a gain of a parastic bipolar transistor operating when static electricity is supplied may be increased according to the depth. In embodiments, electric currents and/or field generated when static electricity is supplied may be dispersed in the depth direction. Such a dispersion of an electric current and/or field may prevent damage to an interface between a substrate and a gate oxide layer, and may reduce abnormal leakage current which results in a high ESD protection characteristic.

### DRAWINGS

Example FIG. 1 is a sectional view illustrating an electrostatic discharge protection grounded gate MOSFET.

Example FIG. 2 is a sectional view illustrating an electrostatic discharge protection semiconductor device according to embodiments.

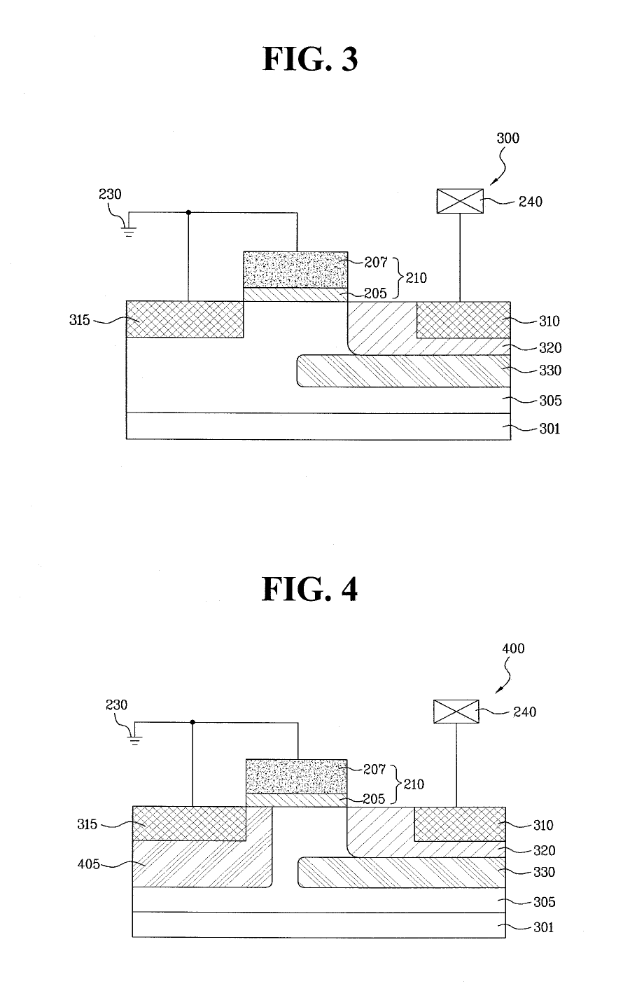

Example FIG. 3 is a sectional view illustrating an electrostatic discharge protection semiconductor device according to embodiments.

Example FIG. 4 is a sectional view illustrating an electrostatic discharge protection semiconductor device according to embodiments.

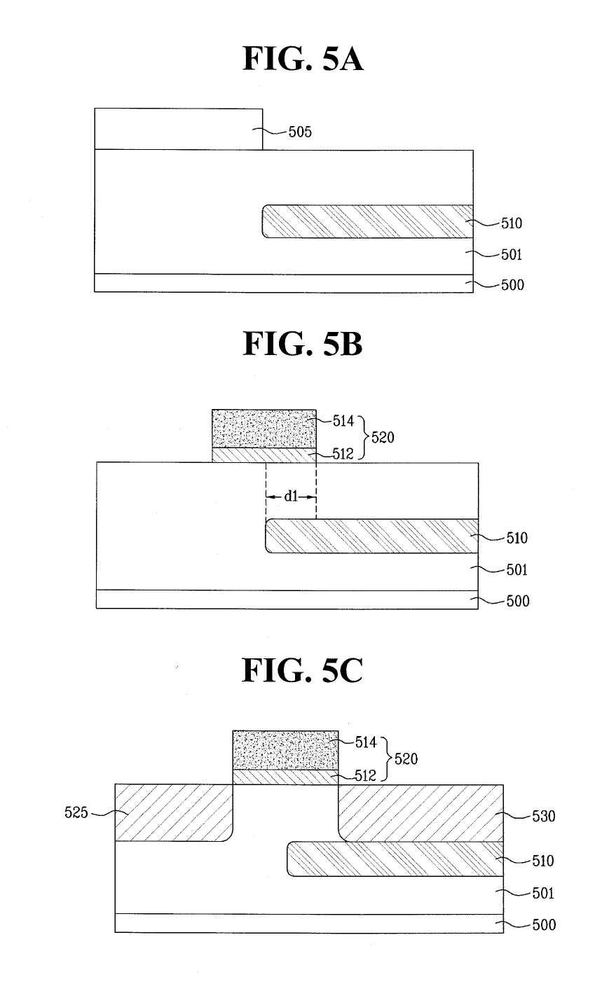

Example FIGS. 5A to FIG. 5C are sectional views illustrating a process of forming an electrostatic discharge protection semiconductor device according to embodiments.

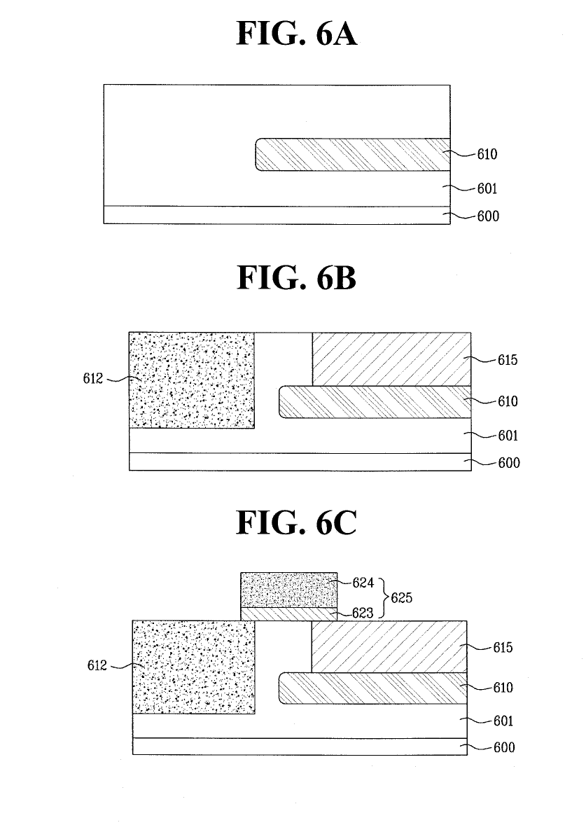

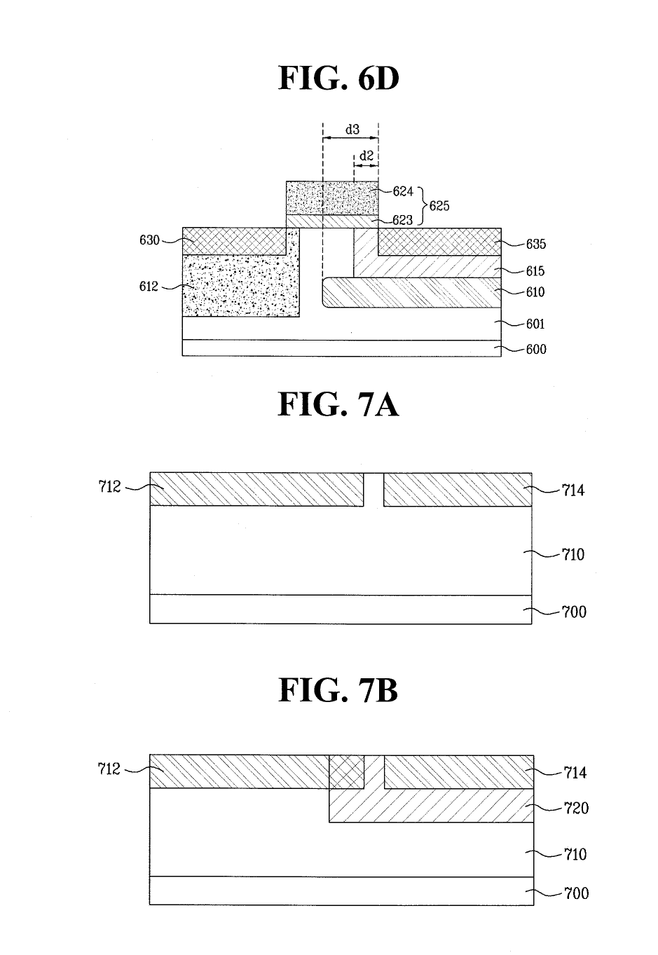

Example FIGS. 6A to 6D are sectional views illustrating a process of forming an electrostatic discharge protection semiconductor device according to embodiments.

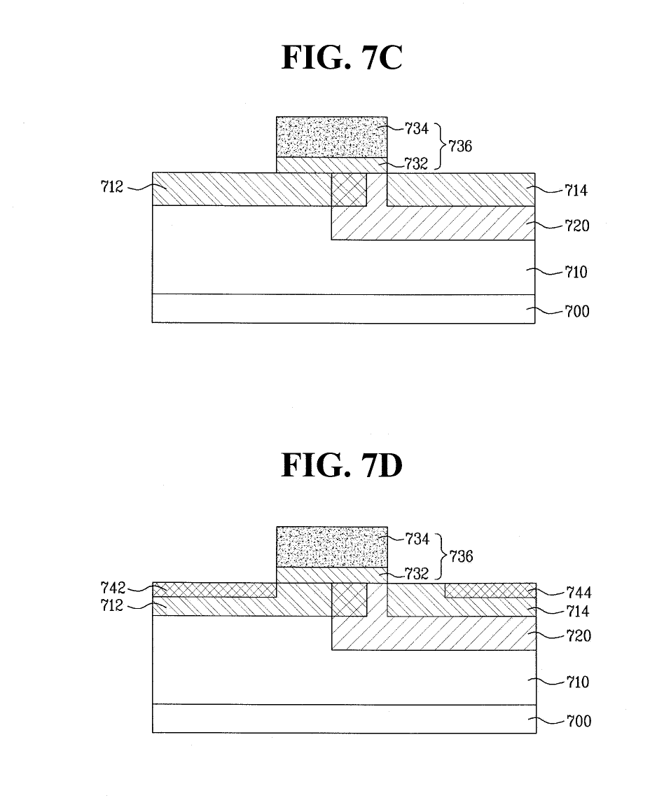

Example FIGS. 7A to 7D are sectional views illustrating a process of forming an electrostatic discharge protection semiconductor device according to embodiments.

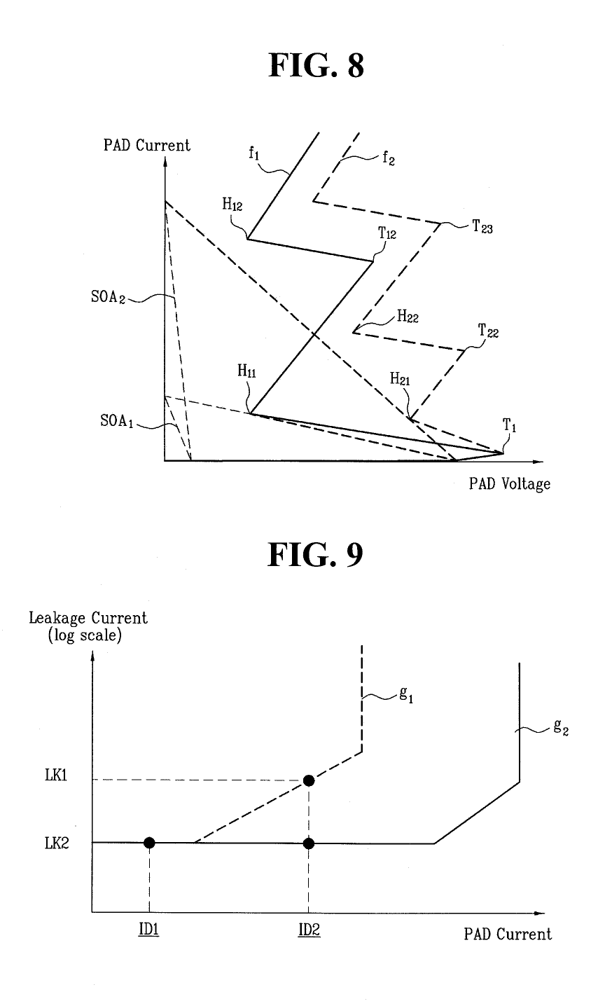

Example FIG. 8 illustrates characteristics of electric current and voltage of an electrostatic discharge protection semiconductor device according to embodiments.

Example FIG. 9 is a graph illustrating leakage current flowing to an electrostatic discharge protection semiconductor device according to embodiments after applying an electrostatic pulse current to a pad connected to the electrostatic discharge protection semiconductor device.

### DESCRIPTION

Embodiments relate to an electrostatic discharge protection semiconductor device. Referring to example FIG. 2, electrostatic discharge protection semiconductor device 200 may include gate 210, source region 215, first drain region 220 and second drain region 225. According to embodiments, gate 210 may include gate oxide layer 205 and gate electrode 207, and may be multi-layered in and/or over substrate 201. In embodiments, source region 215 may be formed in and/or over a predetermined area of substrate 201 on a side of gate 210. In embodiments, first drain region 220 may be formed in and/or over a predetermined area of substrate 201 on an opposing side of gate 210.

According to embodiments, second drain region 225 may be connected to a lower area of first drain region 220. In embodiments, second drain region 225 may be formed relatively deeper compared to first drain 220, and may be partially overlapped with a layout of gate 210 in a horizontal direction. Source region 215, first drain region 220 and/or second drain region 225 may be formed in p-type well 213 formed in and/or over substrate 201, in accordance with embodiments.

According to embodiments, first drain region 220 may be overlapped with gate 210 horizontally, relative to substrate 201, although embodiments are not limited to such a configuration. In embodiments, first drain region 220 may be partially overlapped with gate 210. In embodiments, an overlapped region between first drain region 220 and gate 210 may be substantially larger than an overlapped region between second drain region 225 and gate 210.

Referring to FIG. 2, a first channel between source region 215 and first drain region 220 may be substantially shorter than a second channel between source region 215 and second drain region 225. In embodiments, the first channel may refer to a region of p-type well 213 between source region 215 and first drain region 220. In embodiments, the second channel may refer to a region of p-type well 213 between course region 215 and second drain region 225.

According to embodiments, a first parastic bipolar transistor including source region 215, the first channel, and first drain region 220 may be formed and/or operated in an electrostatic discharge protection semiconductor device when static electricity is supplied to pad 240. In embodiments, a second parasitic bipolar transistor including source region 215, the second channel, second drain region 225 and first drain region 220 may be formed and/or operated when static electricity is supplied to a pad 240. In embodiments, source region 215 may correspond to an emitter of the first and second parastic bipolar transistors, p-type well 213 may correspond to a base, and first and second drain regions 220 and 225, respectively, may correspond to a collector.

According to embodiments, the second parasitic bipolar transistor may be formed relatively deeper compared to the first parasitic bipolar transistor, and the length of the second channel may be relatively smaller compared to the first channel. In embodiments, a base of the second parastic bipolar transistor may be substantially narrower than a base of the first paratsic bipolar transistor. The smaller the width of a base, the maximized an electronic device may perform in operation in accordance with embodiments. In embodiments, the gain of the second parastic bipolar transistor may be substantially and relatively larger than that of the first parastic bipolar transistor.

According to embodiments, the density of impurity doped in second drain region 225 may be relatively higher compared to impurity doped in first drain region 220 and p-well 201 formed in and/or over substrate 210. In embodiments, the density of the impurity doped in p-type well 213 may be approximately between 1E16/cm3 to 1E18/cm3. In embodiments, the density of the impurity doped in first drain region may be approximately 1E16/cm3 to 1E19/cm3, and the density of the impurity doped in second drain region may be approximately 1E17/cm3 to 1E20/cm3.

According to embodiments, source region 215 may be connected to ground terminal 230, and first drain region 220 may be connected to pad 240. An electrostatic discharge protection semiconductor device 200 may further include a resistance, in accordance with embodiments. In embodiments, the resistance may be contacted between first drain region 220 and pad 240 to generate triggering for first drain region 220, for example, in an initial period of static electricity flow to pad 240.

Embodiments relate to a method of manufacturing an electrostatic discharge protection semiconductor device. Example FIGS. 5A to FIG. 5C are sectional views illustrating a process of forming an electrostatic discharge protection semiconductor device in accordance with embodiments. Referring to FIG. 5A, a first conductivity type impurity ion, for example a p-type impurity ion, may be selectively implanted in and/or over substrate 500. According to embodiments, selective implantation may form a first conductivity type first well 501, for example, a p-type well. In embodiments, a second conductivity type impurity ion, for example N-type impurity ion, may be selectively implanted in p-type well 501 to form a second drain region 510.

According to embodiments, a photo lithography process may be performed over substrate 500 to form a first photo resist pattern 505. In embodiments, an n-type impurity ion may be implanted in and/or over substrate 500 by using first photo resist pattern 505 as a mask. In embodiments, second drain region 510 may be formed in a predetermined area of p-type well 501. Second drain region 510 may be formed in a predetermined area of p-type well 501, and may be spaced apart a predetermined distance from a surface of p-type well 501, in accordance with embodiments.

Referring to FIG. 5B, first photo resist pattern 505 may be removed, for example in an ashing process in accordance with embodiments. In embodiments, gate 520 may be overlapped with a predetermined area (d) of second drain region 510 in a horizontal direction, and may be formed over substrate 500. In embodiments, gate 520 may be multi-layered, and may include gate oxide layer 512 and/or gate electrode 514, and gate 520 may be overlapped with a predetermined area of second drain region 510 in accordance with embodiments. In embodiments, an oxide layer and a gate poly may be formed over substrate 500, for example sequentially, and both the oxide layer and the gate poly may be patterned to be overlapped with a predetermined area of second drain region 510. In embodiments, gate 520 may then be formed.

According to embodiments, a second conductivity type impurity ion, for example n-type impurity ion, may be implanted in p-type well 501 by using gate 520 as an ion implantation mask to form first drain region 530 and source region 525. In embodiments, first drain region 530 may be expanded from a surface of p-type well 501 to contact an upper area of second drain region 510. In embodiments, first drain region 530 may be partially overlapped or not overlapped with gate 520 by, for example, adjusting an impurity ion implantation angle. Referring to FIG. 5C, first drain region 530 may not be overlapped with gate 520. However, when there is a region of first drain region 220 in overlap with gate 210 the overlapped portion may be substantially and relatively larger than the portion of overlap between second drain region 225 and gate 210, or vice versa.

Embodiments relate to an electrostatic discharge protection semiconductor device. Referring to example FIG. 3, an electrostatic discharge protection semiconductor device 300 may include gate 210, source region 315, first drain region 310, second drain region 320, and third drain region 330. According to embodiments, gate 210 may includes gate oxide layer 205 and gate electrode 207, and may be multi-layered in and/or over substrate 301. In embodiments, source region 315 may be formed in and/or over a predetermined area of substrate 301 on a side of gate 210. In embodiments, first drain region 310, second drain region 320, and/or third drain region 330 may be formed in and/or over a predetermined area of substrate 301 on an opposing side of gate 210. In embodiments, a first conductivity type well, for example p-type well 305, may be formed in and/or over substrate 310 and electrostatic discharge protection semiconductor device 300 may be formed in p-type well 305.

According to embodiments, first drain region 310 may be formed in and/or over a surface of substrate 301 and may be spaced apart a predetermined distance from gate 210 and/or p-type well 305. In embodiments, first drain region 310 may be connected to pad 240. In embodiments, second drain region 320 may contact gate 210 and/or first drain region 310, and may cover an area between gate 210, first drain region 310, and/or a lower area of first drain region 310. An end portion of second drain region 320 may be formed in contact with a lower area of gate 210 and may be partially overlapped with gate 210 in a horizontal direction, in accordance with embodiments.

According to embodiments, third drain region 330 may be formed in and/or over p-type well 305 under second drain region 320, and may contact second drain region 320. In embodiments, third drain region may be partially overlapped with gate 210 in a horizontal direction. In embodiments, when second drain region 320 is partially overlapped with gate 210, third drain region 330 may be more overlapped with gate 210 compared to second drain region 320 such that second drain region 320 may be more adjacent to source region 315. In embodiments, second drain region 320 may include an substantially similar or the same conductivity type to first drain region 310, for example n-type, and may be formed with less impurity density than first drain region 310.

According to embodiments, a first channel may refer to p-type well 305 region between source region 315 and second drain region 320. In embodiments, a second channel may refer to as p-type well 305 region between source region 315 and third drain region 330. In embodiments, a first parasitic bipolar transistor including source region 315, a first channel, second drain region 320, and first drain region 310 may be formed and/or operated when static electricity is supplied to pad 240. In embodiments, a second parasitic bipolar transistor including source region 315, a second channel, third drain region 330, second drain region 320, and first drain region 310 may be formed and/or operated. Second parasitic bipolar transistor may be formed deeper than first parasitic bipolar transistor, and the gain of the second parastic bipolar transistor may be bigger than that of the first parastic bipolar transistor in accordance with embodiments.

Embodiments relate to a method of manufacturing an electrostatic discharge protection semiconductor device. Example FIGS. 6A to 6D are sectional views illustrating a process of forming an electrostatic discharge protection semiconductor device in accordance with embodiments. Referring to FIG. 6A, a first conductivity type impurity ion, for example p-type impurity ion, may be selectively implanted in and/or over substrate 600 to form a first type well, for example p-type well 601. In embodiments, a second conductivity impurity ion, for example n-type impurity ion, may be selectively implanted in and/or over p-type well 601 to form first drain region 610.

According to embodiments, a photo lithography process may performed over substrate 600. In embodiments, a photo resist pattern may be formed and an n-type impurity ion may be implanted in and/or over substrate 601 by using the photo resist pattern as mask. In embodiments, first drain region 610 may be formed in and/or over p-type well 601. In embodiments, first drain region 610 may be formed in and/or over a predetermined area of p-type well 601, and may be spaced apart at a predetermined distance from a surface of p-type well 601.

Referring to FIG. 6B, a second conductivity type impurity ion may be selectively implanted in and/or over p-type well 601 to form second drain region 615 in and/or over first drain region 610. According to embodiments, second drain region 615 may be expanded from a surface of p-type well 601 of substrate 600 to contact with an upper area of first drain region 610. In embodiments, a photo lithography process may be performed over substrate 600 to form a photo resist pattern. In embodiments, n-type impurity ion may be selectively implanted in and/or over substrate 600. The photo resist pattern may be used as a mask in accordance with embodiments, and second drain region 615 may be formed in and/or over first drain region 610. In embodiments, second drain region 615 may be formed substantially and relatively smaller than the expanded region of first drain region 610 in a horizontal direction.

According to embodiments, a low density second conductivity type impurity ion may be selectively implanted in and/or over p-type well 601 (e.g. first well 601). In embodiments, a p-type well having a lower density relative to first well 601 (e.g., second well 612) may be formed in a predetermined area of first well 601, and may be spaced apart a predetermined distance from first and second drains 610 and 615, respectively. Referring to FIG. 6C, gate 625 may be partially overlapped with first and second drain regions 610 and 615, respectively, and may be partially overlapped with second well 612 which may be formed in and/or over substrate 600. However, gate 625 may be partially overlapped with first drain region 610 and may not be overlapped with second drain region 615 in accordance with embodiments.

Referring to FIG. 6C, gate 625 may include gate oxide layer 622 and gate electrode 624, and may be multi-layered sequentially. In embodiments, an oxide layer and a gate poly may be formed, for example sequentially, in and/or over substrate 600. In embodiments, the gate oxide layer and the gate poly may be patterned to form gate 625 having predetermined areas overlapped with first and second drain regions 610 and 615, respectively. The overlapped region between second drain region 615 and gate 625 may be larger than the overlapped region between first drain region 610 and gate 625, in accordance with embodiments.

Referring to FIG. 6D, a second conductivity type impurity ion, for example n-type impurity ion, may be implanted in second well 612 and second drain region 615. In embodiments, the implantation may be accomplished by using gate 625 as an ion implantation mask. In embodiments, source region 630 may be formed in and/or over a predetermined area of second well 612 on a side of the gate 625. A third drain region 635 may be formed in and/or over a predetermined area of second drain region 615 on an opposing side of the gate 625 relative to source drain 630, in accordance with embodiments.

Referring to FIG. 6D, overlapped region (d3) between first drain 610 and gate 625 may be substantially larger than overlapped region (d2) between second drain region 615 and gate 625. According to embodiments, first drain region 610 may be formed more adjacent to source region 215 compared to second drain region 615. In embodiments, the density of impurity doped in first drain region 610 may be relatively higher compared to the density of impurity doped in second drain region 615. The predetermined area of first drain region 610 overlapped with gate 625 may correspond to approximately 1/10 to ½ the width of gate 625, in accordance with embodiments.

Embodiments relate to an electrostatic discharge protection semiconductor device. Referring to example FIG. 4, an electrostatic discharge protection semiconductor device 400 may be substantially similar to the electrostatic discharge protection semiconductor device 300 illustrated in FIG. 3. However, according to embodiments, second p-well region 405 may have an intermediate density that is relatively higher compared to the relatively low density of p-well region 305 (i.e., first p-well region). In embodiments, second p-well region 405 may be partially overlapped with gate 210 and may be adjacent to source region 315. In embodiments, second p-well region 405 may be formed in and/or over a lower area of source region 315, an area between source region 315 and second drain region 320, and/or an area between source region 315 and third drain region 330.

According to embodiments, density increase of a channel employed as a base of a parasitic bipolar transistor may reduce the gain of the parastic bipolar transistor. According to embodiments, a predetermined area of second p-type well 405 may be formed to be included in a channel to increase the channel density. Therefore, the gain of a parasitic bipolar transistor may be reduced and a holding voltage may be increased.

Embodiments relate to a method of manufacturing an electrostatic discharge protection semiconductor device. Example FIGS. 7A to 7D are sectional views illustrating a process of forming an electrostatic discharge protection semiconductor device in accordance with embodiments. Referring to FIG. 7A, a first conductivity type impurity, for example p-type impurity, may be implanted in and/or over a substrate 700 to form first conductivity type well 710 for high voltage. According to embodiments, more of first conductivity type impurity ion may be selectively implanted in a predetermined area of first conductivity type well 710. In embodiments, an expanded first conductivity type drain 712 may be formed. In embodiments, a second conductivity type impurity ion, for example n-type impurity ion, may be selectively implanted in and/or over another predetermined area of first conductivity type well 710. In embodiments, an expanded second conductivity type drain 714 may be adjacent to, or may be spaced apart from, expanded first conductivity type drain 712 formed.

Referring to FIG. 7B, second conductivity type impurity ion may be selectively implanted in and/or over first conductivity type well 710 in accordance with embodiments. In embodiments, a second conductivity type well 720 may be formed under and/or on a side of second conductivity type drain 714, and may be partially overlapped with first conductivity type drain 712.

Referring to FIG. 7C, gate 736 may include oxide layer 732 and gate electrode 734. In embodiments, gate 736 may be multi-layered, for example sequentially, and may be formed in and/or over substrate 700 in accordance with embodiments. In embodiments, gate 736 may be formed in and/or over substrate 700, and may be overlapped with a predetermined area of expanded first conductivity type drain 712. In embodiments, gate 736 may be overlapped with a predetermined area between expanded first and second conductivity type drains 712 and 714, respectively, and may be overlapped with a predetermined area of second conductivity type well 720.

Referring to FIG. 7D, second conductivity type impurity ion may be implanted in and/or over a predetermined area of substrate 700 on both sides of gate 736 in accordance with embodiments. In embodiments, source region 742 may be formed in and/or over first conductivity type drain 712. In embodiments, a drain region 744 may be formed in and/or over expanded second conductivity type drain 714.

Referring to FIG. 8, characteristics of electric currents and voltage for an electrostatic discharge protection semiconductor device according to embodiments is illustrated when static electricity is supplied. A comparison of an electric current and voltage between an electrostatic discharge semiconductor device and an electrostatic discharge protection semiconductor device in accordance with embodiments is described. A safe operation area (SOA2) of an electrostatic discharge semiconductor device according to embodiments is maximized compared to a safe operation area (SOA1) of an electrostatic discharge semiconductor. An electrostatic discharge semiconductor device according to embodiments has maximized holding voltages compared with holding voltages of an electrostatic discharge semiconductor device (e.g., H11 and H12). Although the devices may have substantially the same initial triggering voltage (i.e., T1 or first triggering voltage), subsequent triggering voltages (e.g., T22 and/or T23) of an electrostatic discharge semiconductor device in accordance with embodiments are maximized compared to the other triggering voltage (e.g., T12) of an electrostatic discharge semiconductor device.

Also, while thermal runaway occurs at the second triggering voltage (e.g., T12) of an electrostatic discharge semiconductor, intermediate snap back (e.g., T1-H21-T22-H22-T3) is formed before thermal runaway may occur and both the holding voltage and current are increased to expand the SOA2 of an electrostatic discharge semiconductor device according to embodiments. In embodiments, electric current may be diffused in a deep area of a substrate to prevent electric currents from being concentrated over an interface between a substrate and a gate oxide layer, such that a second triggering voltage (e.g., T23), which may cause the thermal runaway, may be maximized.

Referring to FIG. 9, leakage current that may flow after applying an electrostatic pulse current to a pad connected to an electrostatic discharge protection semiconductor device in accordance with embodiments is illustrated. Plot (g1) illustrates leakage currents of an electrostatic discharge protection semiconductor device. Plot (g2) illustrated leakage current of an electrostatic discharge protection semiconductor device according to embodiments. As illustrated, if a value of an electrostatic pulse current applied to a pad (ID1) is relatively small, the leakage current (LK2) flowing for both of the devices may be substantially uniform. However, if a value of an electrostatic pulse current applied to a pad (ID2) is relatively large, there is damage to an interface between a substrate and a gate oxide layer in an electrostatic discharge protection semiconductor device. Moreover, abnormal leakage current (LK1) flows in an electrostatic discharge protection semiconductor device. In contrast, leakage current has relatively little change in an electrostatic discharge protection semiconductor device according to embodiments, for example in the devices illustrates in example FIG. 2 to example FIG. 4.

According to embodiments, electric current and field may be dispersed via multi-channels. In embodiments, the multi-channels may have different lengths according to their depth when an electrostatic discharge protection semiconductor device in accordance with embodiments is turned on by an applied electrostatic pulse. An electrostatic discharge protection semiconductor device in accordance with embodiments may be turned on by an applied electrostatic pulse to prevent damage to an interface between a substrate and a gate oxide layer, and to gain a high ESD protection characteristic.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a substrate;
a gate;
a source region; and
a plurality of drain regions comprising a first drain region and a second drain region, wherein said second drain region is formed deeper in the substrate than said first drain region.

2. The apparatus of claim 1, wherein:
the substrate comprises a semiconductor substrate;
the gate is multi-layered and comprises at least one of a gate oxide layer, a gate electrode layer and a gate poly;
the source region is formed in the substrate on a side of the gate; and
at least one of said first drain region and said second drain region is formed in the substrate on an opposing side of the gate relative to the source region.

3. The apparatus of claim 1, wherein said plurality of drain regions are sequentially multi-layered in a vertical direction.

4. The apparatus of claim 1, wherein at least one of said first drain region and said second drain region is overlapped with the gate in a horizontal direction.

5. The apparatus of claim 4, wherein said first drain region is adjacent the gate.

6. The apparatus of claim 4, wherein said first drain region is spaced apart from the gate.

7. The apparatus of claim 4, wherein said first drain region and said second drain region are overlapped with the gate to form a plurality of overlapped areas such that the size of the areas increase in a direction toward a lower area of the substrate.

8. The apparatus of claim 7, wherein the overlapped area between said first drain region and the gate is substantially smaller than the overlapped area between said second drain region and the gate.

9. The apparatus of claim 8, wherein said first drain region and said second drain region is substantially completely overlapped with the gate in a horizontal direction.

10. The apparatus of claim 1, comprising:
a first conductivity type first well formed in the substrate, wherein the source region, said first drain region and said second drain region are formed in the first conductivity type well.

11. The apparatus of claim 10, wherein the density of impurity doped in the second drain is relatively higher than the density of impurity doped in the first drain region.

12. The apparatus of claim 1, comprising:
the gate adjacent the source region; and
a first conductivity type second well formed adjacent the source region and overlapped with the gate.

13. A method comprising:
forming a first conductivity type first well by implanting a first conductivity type impurity ion in a substrate;
forming at least one lower drain region by implanting a second conductivity type impurity ion in the first well;
forming a gate over the substrate; and
forming an upper drain region in contact with an upper area of the at least one lower drain region by implanting the second conductivity type impurity ion in the first well.

14. The method of claim 13, wherein the at least one lower drain region is multi-layered in the first conductivity type first well, and is spaced apart at a predetermined distance from a surface of the conductivity type first well.

15. The method of claim 13, wherein the gate is overlapped with a predetermined area of the at least one lower drain region in a horizontal direction.

16. The method of claim 13, wherein the gate operates as an ion implantation mask to form the upper drain region.

17. The method of claim 13, wherein forming the at least one lower drain region increases the at least one lower drain region downwardly from a top thereof in a horizontal direction.

18. The method of claim 17, wherein forming the at least one lower drain region comprises:
forming a first drain region by selectively implanting the second conductivity type impurity ion in the first well; and
forming a second drain region expanded to contact an upper area of the first drain by implanting the second conductivity type impurity ion in the first well.

19. The method of claim 18, wherein forming the gate comprises at least one of:
forming the gate on the substrate overlapped with the first and second drain regions; and
forming the gate on the substrate overlapped with the first drain region and not with the second drain region.

20. The method of claim 18, comprising:
forming a second well having a higher density relative to the first well in the first well and adjacent to the source region, wherein the second well is spaced apart from first and second drain regions.
